(19) United States
(12) Patent Application Publication
(10) Pub. No.: US 2023/0029202 A1
(43) Pub. Date: Jan. 26, 2023

(54) CONTACT STRUCTURE FORMING METHOD, CONTACT STRUCTURE, AND SEMICONDUCTOR DEVICE

(71) Applicant: CHANGXIN MEMORY TECHNOLOGIES, INC., Hefei City (CN)

(72) Inventors: Xin HUANG, Hefei City (CN); Shih-Shin Wang, Hefei City (CN)

(21) Appl. No.: 17/451,179

(22) Filed: Oct. 18, 2021

Related U.S. Application Data
(63) Continuation of application No. PCT/CN2021/110890, filed on Aug. 5, 2021.

(30) Foreign Application Priority Data
Jul. 21, 2021 (CN) 202110824913.5

(51) Int. Cl. H01L 21/768; H01L 23/528; H01L 21/762; H01L 21/311

(52) U.S. Cl. CPC H01L 21/76816; H01L 23/5283; H01L 21/76224; H01L 21/31144; H01L 21/31116; H01L 27/10844

(57) ABSTRACT

The embodiments of the present application disclose a contact structure forming method, a contact structure, and a semiconductor device. The method includes: providing a substrate, the substrate having a plurality of isolation regions therein, the isolation regions isolating an active region on the substrate into several portions; etching the active regions and the isolation regions simultaneously by the first etching processing, to form a first contact hole, a protruding active region being formed at the active region in the bottom of the first contact hole; depositing a first dielectric layer to cover the sidewall and bottom of the first contact hole; and etching the bottom of the first contact hole by the second etching processing, to form a contact structure having a target depth.

### CROSS-REFERENCE TO RELATED APPLICATIONS

This application is a continuation application of International Patent Application No. PCT/CN2021/110890, filed on Aug. 5, 2021, which claims priority to Chinese Patent Application No. 202110824913.5, filed with the Chinese Patent Office on Jul. 21, 2021 and entitled “CONTACT STRUCTURE FORMING METHOD, CONTACT STRUCTURE, AND SEMICONDUCTOR DEVICE.” International Patent Application No. PCT/CN2021/110890 and Chinese Patent Application No. 202110824913.5 are incorporated herein by reference in their entireties.

### TECHNICAL FIELD

The present application relates to, but not limited to, the field of semiconductor technologies, and in particular to a contact structure forming method, a contact structure, and a semiconductor device.

### BACKGROUND

As a line width of dynamic random access memories (DRAM) is gradually decreased, the size of the structure to be formed is reduced, resulting in a reduction in the size of the contact structure to be formed.

During a semiconductor process, when different materials need to be etched in the same procedure, there are different etching rates for these different materials while etching, so in a process for simultaneous etching of different materials, an uneven step structure will be formed at the junction of the different materials after etching. In particular, if the uneven step structure is formed in the bottom of the contact structure and the size of the contact structure is reduced at the same time, then it will be extremely difficult to completely fill up the uneven step structure with a conductive material that needs to fill the contact structure later. As a result, the electric performance of the subsequently-formed semiconductor structure is affected and further, the yield of the semiconductor structure is lowered. In a worse case scenario, voids will be created and wafers will be scrapped accordingly.

### SUMMARY

The embodiments of the present application provide a contact structure forming method, a contact structure and a semiconductor device.

According to some embodiments, a first aspect of the present application provides a contact structure forming method, which includes:

providing a substrate, the substrate having a plurality of isolation regions therein, the isolation regions isolating an active region on the substrate into several portions; etching the active regions and the isolation regions simultaneously by a first etching processing, to form a first contact hole, a protruding active region being formed at the active region in the bottom of the first contact hole; depositing a first dielectric layer to cover the sidewall and bottom of the first contact hole; and etching the bottom of the first contact hole by a second etching processing, to form a contact structure having a target depth.

According to some embodiments, a second aspect of the present application provides a contact structure, which is formed using the forming method.

According to some embodiments, a third aspect of the present application also provides a semiconductor device, which includes the contact structure.

### BRIEF DESCRIPTION OF DRAWINGS

In order to more clearly illustrate the embodiments of the present application or the technical solutions of the traditional technology, the accompanying drawings required to be used in the embodiments will be briefly introduced below. Apparently, the accompanying drawings in the following description show merely some embodiments of the present application, and persons of ordinary skill in the art may still derive other drawings from these accompanying drawings without creative efforts.

FIG. 1 is a flow chart illustrating the contact structure forming method in an embodiment of the present application; and

FIG. 2 to FIG. 8 are schematic structural sectional diagrams corresponding to various steps in the contact structure forming method according to an embodiment of the present application.

### DESCRIPTION OF EMBODIMENTS

During a semiconductor process, when different materials need to be etched in the same procedure, there are different etching rates for these different materials while etching, so in a process for simultaneous etching of different materials, an uneven step structure will be formed at the junction of the different materials after etching. In particular, if the uneven step structure is formed in the bottom of the contact structure and the size of the contact structure is reduced at the same time, then it will be extremely difficult to completely fill up the uneven step structure with a conductive material that needs to fill the contact structure later. As a result, the electric performance of the subsequently-formed semiconductor structure is affected and further, the yield of the semiconductor structure is lowered.

To solve the above problem, an embodiment of the present application provides a contact structure forming method, which includes: providing a substrate, the substrate having a plurality of isolation regions therein, the isolation regions isolating an active region on the substrate into several portions; etching the active regions and the isolation regions simultaneously by a first etching processing, to form a first contact hole, a protruding active region being formed at the active region in the bottom of the first contact hole; depositing a first dielectric layer to cover the sidewall and bottom of the first contact hole; and etching the bottom of the first contact hole by a second etching processing, to form a contact structure having a target depth.

In order to make the objectives, the technical solutions, and the advantages of the embodiments of the present application clearer, the detailed description of the embodiments of the present application is given below in combination with the accompanying drawings. The ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized. The following embodiments are divided for convenience of description, and should not constitute any limitation to the implementation of the present application. The embodiments may be combined with each other and referred to each other without contradiction.

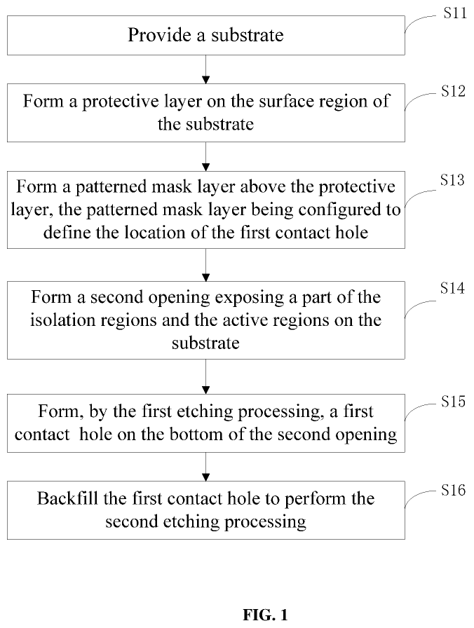

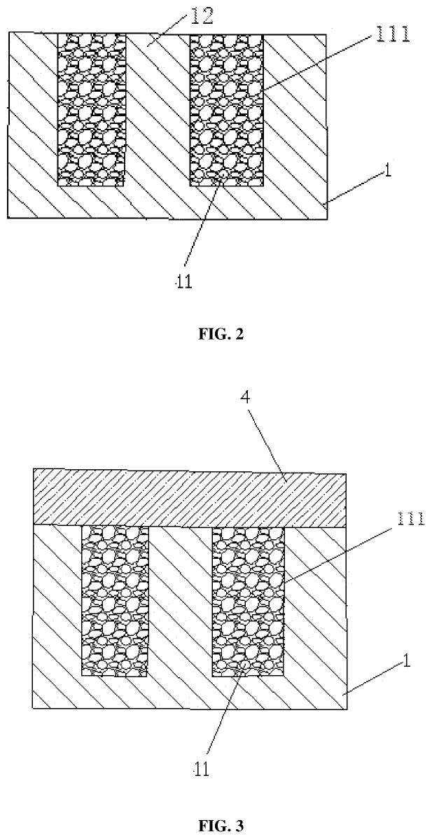

FIG. 1 is a flow chart illustrating the contact structure forming method in an embodiment of the present application, and FIG. 2 to FIG. 8 are schematic structural sectional diagrams corresponding to various steps in the contact structure forming method according to an embodiment of the present application. The contact structure forming method according to this embodiment will be further described in detail below in conjunction with the accompanying drawings, and specifically includes the following steps.

As shown in FIG. 1 and FIG. 2, S11: providing a substrate; the substrate 1 includes isolation regions 11, active regions 12 and a word line structure 13.

The material of the substrate 1 may include a semiconductor substrate, a silicon on insulator (SOI) substrate, a germanium on insulator (GOI) substrate, a single crystal metal oxide substrate or the like. In this embodiment, the substrate 1 is made of a silicon material. The reason why the substrate 1 is made of the silicon material in this embodiment is to facilitate understanding of the subsequent forming method by those skilled in the art, without constituting any limitation. The suitable material for the substrate 1 may be chosen based on requirements during actual application.

In particular, a plurality of active regions 12 are arranged in parallel at intervals in the substrate 1. It is to be noted that the substrate 1 further includes other memory structures than the isolation regions 11, the active regions 12 and the word line structure 13. Description is not given here since these other memory structures are not related to the core technology of the present application. Those skilled in the art will appreciate that the substrate 1 further includes other memory structures than the isolation regions 11, the active regions 12 and the word line structure 13, which are configured for normal operation of the memory.

With reference to FIG. 2, a plurality of deep trenches 111 are formed on a surface region of the substrate 1, and the deep trench 111 is filled with an isolation material, so as to form the isolation region 11. The isolation regions 11 isolate the active region 12 on the substrate 1 into several portions. The isolation regions 11 may isolate, on the substrate 1, the active region 12 into several portions that are distributed in the form of an array or in other modes. The active region 12 may be formed by implanting impurities into the substrate 1, e.g., the active region 12 may be formed by ion implantation.

In other embodiments, the isolation material may include silicon oxide, tetraethyl silicate, boro phosphosilicate Glass, or the like.

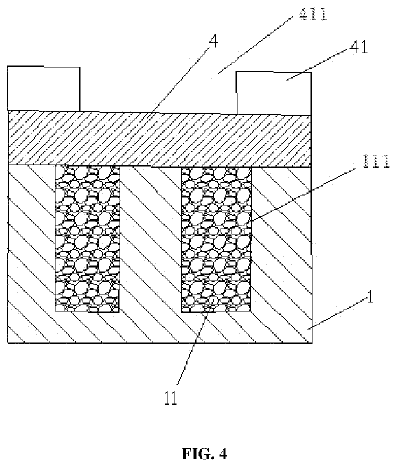

Referring to FIG. 2 and FIG. 3, S12: forming a protective layer on the surface region of the substrate.

The surface region of the substrate 1 is covered with a protective layer 4, and the protective layer 4 may be formed on the substrate 1 using oxide, nitride, oxynitride or the like.

In an example, the protective layer 4 may include silicon oxide, silicon nitride, silicon oxynitride or the like. For example, the protective layer 4 may be formed using undoped silicate glass (USG), spin on glass (SOG), phosphosilicate glass (PSG), borosilicate glass (BSG), boro-phosphosilicate glass (BPSG), flowable oxide (FOX), tetraethylorthosilicate (TEOS), plasma enhanced TEOS (PE-TEOS), Tonen silazane (TOSZ), high density plasma chemical vapor deposition (HDP-CVD)oxides, or the like. These may be used alone or in combination. In addition, the protective layer 4 may be formed using spin coating, chemical vapor deposition (CVD), plasma enhanced chemical vapor deposition (PECVD), high density plasma chemical vapor deposition (HDP-CVD), or the like.

In other embodiments, the protective layer 4 may have a multilayered structure, which may include an oxide film, a nitride film and/or an oxynitride film formed on the substrate 1 in sequence.

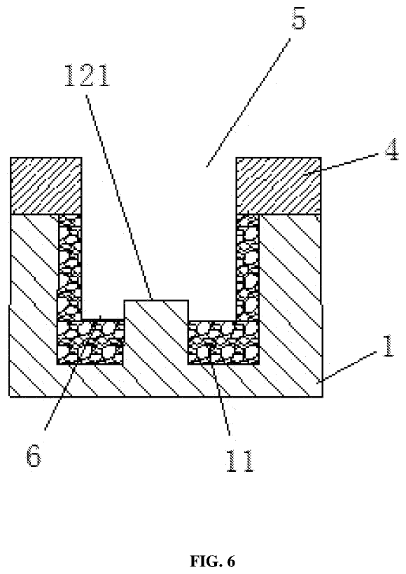

As shown in FIG. 2, FIG. 4 and FIG. 6, S13: forming a patterned mask layer above the protective layer, the patterned mask layer being configured to define the location of the first contact hole.

In detail, the patterned mask layer 41 has a first opening 411 penetrating through the thickness of the mask layer, and the patterned mask layer 41 and the first opening 411 are configured to define the location of the first contact hole.

In an example, forming a first opening 411 penetrating through the thickness of the mask layer includes: forming a graphical photoresist (not shown in the drawing) on the top of the mask layer, and based on the graphical photoresist, forming the first opening 411 inside the mask layer, so as to form the patterned mask layer 41. In addition, it is to be noted that the patterned mask layer 41 may be of a single-layer mask structure, and may also be of a multilayer mask structure.

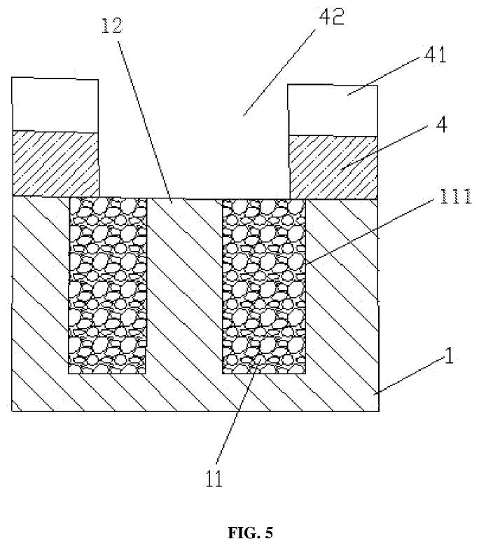

As shown in FIG. 2 and FIG. 5, S14: forming a second opening exposing a part of the isolation regions and the active regions on the substrate.

In particular, in case that the patterned mask layer 41 in S13 serves as a mask, an appropriate etching procedure (for example: wet etching by which phosphoric acid (H₃PO₄) is used as an etchant or dry etching by which N₂ plasma is used as an etching gas) is utilized to etch the protective layer 4 exposed out of the first opening 411, until the second opening 42 that runs through the protective layer 4 is formed. The second opening 42 may expose a part of the isolation regions 11 and the active regions 12 on the substrate 1.

As shown in FIG. 2, FIG. 5 and FIG. 6, S15: forming, by the first etching, a first contact hole in the bottom of the second opening.

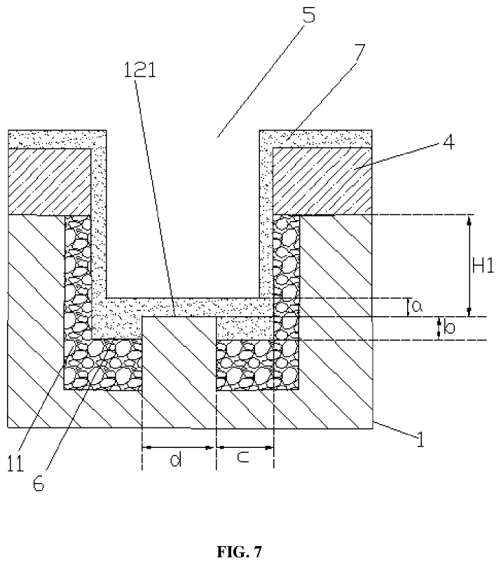

In particular, the active regions 12 and the isolation regions 11 that are exposed in the bottom of the second opening 42 are simultaneously etched by the first etching processing, so as to form the first contact hole 5. The width of the first contact hole 5 is equal to the width of the second opening 42 in a direction parallel to the surface of the substrate 1. A protruding active region 121 is formed at the active region 12 in the bottom of the first contact hole 5. As shown in FIG. 7, the formed protruding active region 121 has a width d.

In an example, in a direction perpendicular to the surface of the substrate 1, the first contact hole 5 has a depth of 20 nm to 40 nm, e.g., 20 nm, 30 nm or 40 nm.

In this embodiment, at the time of the first etching, silicon oxide filled in the isolation region 11 has a different etching selectivity than the etching selectivity of the material of the active region 12, and the etching rate for the isolation region 11 is greater than the etching rate for the active region 12. Thus in the first etching, the depth at which the isolation region 11 is etched is greater than the depth at which the active region is etched, namely the filling material inside the isolation region 11 is removed faster. Therefore, when the first etching comes to an end, the protruding active region 121 that protrudes from the bottom of the isolation region 11 will be formed at the active region 12 in the bottom of the first contact hole 5, i.e., a first height difference is generated between the top of the protruding active region 121 in the bottom of the first contact hole 5 and the upper surface of the isolation region 11 in the bottom of the first contact hole 5. The first height difference is b, as illustrated in FIG. 7.

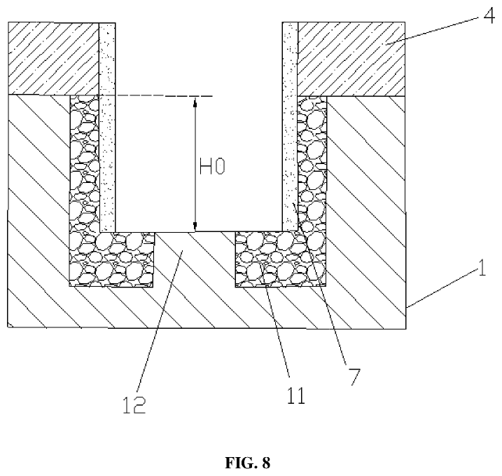

As shown in FIG. 7 and FIG. 8, with respect to the first contact hole 5 formed by the first etching, the depth inside the first contact hole 5, which is corresponding to the protruding active region 121, is less than the target depth of the first contact hole 5. For instance, the etching depth H1 for the active region 12 in the first etching is three quarter of the target depth H0. Since the protruding active region 121 protrudes from the bottom of the first contact hole 5, a trench 6 will be formed between the sidewall of the protruding active region 121 and the sidewall of the first contact hole 5.

In some embodiments, the formed protruding active region 121 is positioned in the center of the bottom of the first contact hole 5, and the distances from the both sides of the protruding active region 121 to the two corresponding sidewalls of the first contact hole 5 are both a first width. As shown in FIG. 7, the first width is c.

Owing to the presence of the first height difference b, it is extremely difficult to completely fill up the uneven step structure with a conductive material that fills the contact structure later. As a result, the electric performance of the subsequently-formed semiconductor structure is affected and further, the yield of the semiconductor structure is lowered. Hence, the second etching is performed for the purpose of reducing the first height difference b.

As shown in FIG. 2 and FIG. 7, S16: backfilling the first contact hole to perform the second etching.

According to the embodiments of the present application, a first dielectric layer 7 is conformally deposited on the sidewall and bottom of the first contact hole 5 as well as on the protruding active region 121 using chemical vapor deposition (CVD) and other suitable processes. According to the embodiments of the present application, the first dielectric layer 7 conformally covers the surface region of the protective layer 4, the sidewall and bottom of the first contact hole 5, and the protruding active region 121. As shown in FIG. 7, the thickness of the first dielectric layer 7 deposited on the protruding active region 121 is a.

In an example, the thickness a of the first dielectric layer 7 deposited on the protruding active region 121 is greater than or equal to one half of the first width c. Then, the trench 6 can be filled up when the first dielectric layer 7 is conformally deposited on the sidewall and bottom of the first contact hole 5 as well as on the protruding active region 121.

As shown in FIG. 7 and FIG. 8, the first dielectric layer 7 on the sidewall and bottom of the first contact hole 5 and the protruding active region 121 in the bottom are simultaneously etched by the second etching processing by utilizing anisotropic etching, thereby forming a contact structure having the target depth H0. The distance from the top of the active region 12 in the bottom of the contact structure to the surface of the isolation region 11 in the bottom of the contact structure is a second height difference. The second height difference is less than the first height difference b, and preferably is 0.

In an example, the distance from the top of the protruding active region 121 to the bottom surface of the first contact hole 5 is a first height, i.e., the first height difference b. The first height is greater than the thickness a of the first dielectric layer 7 deposited on the protruding active region 121, and the thickness d of the protruding active region 121 is greater than the first width c.

In this embodiment, the etching rate for the active region 12 in the second etching is the same as the etching rate for the active region 12 in the first etching.

It is to be noted that the etching rate for the first dielectric layer 7 in the second etching is the same as the etching rate for the isolation region 11 in the first etching. For example, the material of the first dielectric layer 7 may be the same as or different from the filling material of the isolation region 11. In the embodiments of the present application, the material of the first dielectric layer 7 and the filling material inside the isolation region 11 are the same and are both silicon oxide.

For ease of understanding, the height difference between the active region and the isolation region after immediate etching is compared with the height difference after stepwise etching in this embodiment.

It is assumed that the target depth H0 of the active region is 40 nm, the etching rate for the material inside the isolation region is 1.5 times of the etching rate for the material of the active region, and the surface is set to be completely flat during filling of the first dielectric layer.

If the target depth is achieved by means of immediate etching, then:

the target depth of the active region is 40 nm, the target depth of the isolation region is 60 nm, and thus the height difference between the both is 20 nm.

If the target depth is achieved by means of stepwise etching, then:

the first etching is intended to reach ¾ of the target depth, the target depth of the active region is 30 nm, the target depth of the isolation region is 45 nm, and thus the height difference between the active region and the isolation region subsequent to the first etching is 15 nm.

The thickness for backfilling the first dielectric layer on the active region is set as 5 nm, as a result of which the target depth of the active region becomes 25 nm. The bottom of the active is made flush with the bottom of the isolation region, and at this moment, as for the target depth of the isolation region, a backfilling of 20 nm is desired, which mainly is the height difference 15 nm between the active region and the isolation region plus the thickness 5 nm of the first dielectric layer. In this case, the depth of the isolation region becomes 25 nm, which is obtained by subtracting the backfilling of 20 nm from 45 nm.

In the second etching, etching for the target depth of the active region continues, until 40 nm is reached. In particular, another etching of 15 nm to 40 nm is carried out on the basis that the target depth becomes 25 nm after the first etching and the backfilling. The depth that is etched off consists mainly of the thickness 5 nm of the first dielectric layer and 10 nm of the active region.

The target depth 25 nm of the isolation region after the backfilling keeps being etched until 45 nm is reached, the depth that is etched off is mainly the thickness 20 nm of the filled first dielectric layer, and therefore the height difference between the active region and the isolation region is 5 nm. It thus can be seen that stepwise etching can reduce the height difference between the active region and the isolation region.

Compared with the related art, the thickness at which the first dielectric layer is deposited is adjusted depending on the first height difference between the protruding active region formed after the first etching and the bottom of the first contact hole, the height difference caused by the protruding active region is eliminated by covering the sidewall and bottom of the first contact hole with a first dielectric layer, and the target depth is achieved by performing the second etching. In this way, the height difference of the bottom of the first contact hole on the surfaces of different dielectric layers is reduced, the issue is prevented that the conductive material which needs to fill the contact structure later fails to realize a complete filling, the electric performance of the subsequently-formed semiconductor structure is improved, and thus the yield is increased.

Accordingly, another embodiment of the present application relates to a contact structure, which may be manufactured using any of the above forming methods.

Accordingly, another embodiment of the present application also relates to a semiconductor device, which includes the contact structure.

It is to be understood that the above specific implementations of the present application are used only to exemplify or explain the principle of the present application, and do not constitute a limitation to the present application. Therefore, any modification, equivalent substitution, improvement, or the like made without departing from the spirit and scope of the present application shall be included in the protection scope of the present application. In addition, the appended claims of the present application are intended to cover all variation and modification examples that fall within the scope and boundary of the appended claims, or within the equivalent forms of such scope and boundary.

What is claimed is:

1. A contact structure forming method, comprising:
providing a substrate, the substrate having a plurality of isolation regions therein, the isolation regions isolating the substrate into several active regions;
etching the active regions and the isolation regions simultaneously by a first etching processing, to form a first contact hole, a protruding active region being formed at the active region in a bottom of the first contact hole;
depositing a first dielectric layer to cover sidewall and the bottom of the first contact hole; and
etching the bottom of the first contact hole by a second etching processing, to form a contact structure having a target depth.

2. The forming method according to claim 1, wherein an etching rate for the isolation region is greater than an etching rate for the active region.

3. The forming method according to claim 1, wherein a first height difference is generated between a top of the protruding active region in the bottom of the first contact hole and the bottom of the first contact hole.

4. The forming method according to claim 3, wherein a distance from the top of the active region in a bottom of the contact structure to a surface of the isolation region in the bottom of the contact structure is a second height difference, and the second height difference is less than the first height difference.

5. The forming method according to claim 1, wherein in the first contact hole formed by the first etching processing, in the first contact hole, a depth of the protruding active region is less than the target depth of the first contact hole.

6. The forming method according to claim 5, wherein an etching depth for the active region in the first etching processing is three quarter of the target depth.

7. The forming method according to claim 5, wherein the protruding active region is positioned in a center of the bottom of the first contact hole, and distances from both sides of the protruding active region to the two corresponding sidewalls of the first contact hole are both a first width.

8. The forming method according to claim 7, wherein the first dielectric layer has a deposition thickness greater than or equal to one half of the first width.

9. The forming method according to claim 8, wherein a distance from a top of the protruding active region to a bottom surface of the first contact hole is a first height, and the first height is greater than the deposition thickness.

10. The forming method according to claim 1, wherein an etching rate for the isolation region in the first etching processing is the same as an etching rate for the first dielectric layer in the second etching processing, and an etching rate for the active region in the first etching processing is the same as an etching rate for the active region in the second etching processing.

11. The forming method according to claim 1, wherein at least one of a material of the isolation region or a material of the first dielectric layer comprises silicon oxide, and a material of the active region comprises silicon.

12. The forming method according to claim 1, wherein performing the first etching processing on the active region and the isolation region comprises: forming a protective layer on a surface of the substrate and forming a patterned mask layer above the protective layer, the patterned mask layer being configured to define a location of the first contact hole.

13. A contact structure, which is formed using the forming method according to claim 1.

14. A semiconductor device, which comprises the contact structure according to claim 13.
